(19) United States
(12) Patent Application Publication
(10) Pub. No.: US 2004/0091824 A1
(43) Pub. Date: May 13, 2004

(54) Method for reclaiming alkyl esters

(76) Inventors: David Calvin Bradford, Winston Salem, NC (US); Constance Marie Hendrickson, Irving, TX (US)

Correspondence Address: BLANK ROME LLP, 600 NEW HAMPSHIRE AVENUE, N.W., WASHINGTON, DC, 20037, US

(21) Appl. No.: 10/627,712

(22) Filed: Jul. 28, 2003

Related U.S. Application Data
(63) Continuation-in-part of application No. 10/437,305, filed on May 14, 2003.
Application No. 10/437,305 is a division of application No. 09/993,912, filed on Nov. 27, 2001, now Pat. No. 6,582,886.

(51) Int. Cl. G03F 7/32; B03B 5/64

(52) U.S. Cl. 430/399; 209/199; 209/132; 209/155

(57) ABSTRACT

The present invention provides methods of reclaiming and recycling the polymer-contaminated solvent that was used in the developing process for the preparation of relief plates crosslinked by photopolymerization. The solvent of the present system contains alkyl esters, alone or in combination with co-solvents and/or non-solvents, as washout solvents for the unpolymerized material in the printing plates to develop a relief image and a method for developing printing plates. The process comprises transferring the contaminated solvent, from a plate processor or a dirty holding tank, to a centrifuge, and centrifuging the contaminated solvent to remove the polymer. The reclaimed solvent can be transfer directly back to the plate processor or to a clean holding tank.

This application is a continuation-in-part (CIP) of U.S. patent application Ser. No. 10/437,305, filed May 14, 2003, which is a divisional of U.S. patent application Ser. No. 09/993,912, filed Nov. 27, 2001, now U.S. Pat. No. 6,582,886.

### FIELD OF THE INVENTION

The present invention relates to an improved solvent for use in the production of flexographic printing plates crosslinked by photopolymerization and methods for reclaiming and recycling the solvent. More specifically, the invention relates to a solvent system using alkyl esters, alone or in combination with co-solvents and/or non-solvents, as washout solvents for the unpolymerized material in the printing plates to develop a relief image and a method for developing printing plates. The polymer-contaminated solvent can then be reclaimed or recycled through centrifugation.

### BACKGROUND OF THE INVENTION

Washout processes for the development of photopolymerizable flexographic printing plates are well known and is described in detail in U.S. Pat. No. 5,240,815 which is incorporated herein by reference. Ordinarily, exposed plates are washed (developed) in a developing solvent that can remove the unpolymerized material while leaving the polymerized (cured) material intact. The solvent typically used in such processes include: (a) chlorohydrocarbons, such as trichloroethylene, perchloroethylene or trichloroethane, alone or in a mixture with a lower alcohol, such as n-butanol; (b) saturated cyclic or acyclic hydrocarbons, such as petroleum ether, hexane, heptane, octane, cyclohexane or methylcyclohexane; (c) aromatic hydrocarbons, such as benzene, toluene or xylene; (d) lower aliphatic ketones, such as acetone, methyl ethyl ketone or methyl isobutyl ketone; and (e) terpene hydrocarbons, such as d-limonene.

One important disadvantage of the known solvents and the procedures for their use is that the solvents being used as developers may act too slowly, causing swelling of the plates and/or damage to the fine detail in the plate by undercutting and/or pinholing. Moreover, when non-chlorinated solvents are used in the washout process, long drying times may be necessary. Furthermore, many of these solvents have flashpoints of less than 100° F., so that the process can only be operated in special, explosion-protected plants. Many of the prior art solvents are considered Hazardous Air Pollutants (HAPS), and are subject to stringent reporting requirements. When chlorohydrocarbons and other toxic chemicals are used, their toxicity also gives rise to disposal problems and worker safety issues.

An essential step to any photopolymerizable relief printing process is the development of the printing plate after the image is formed through imagewise exposure of the photopolymerizable plate to light. The image is formed by polymerizing and crosslinking of the photopolymerizable material that is exposed while the unexposed portion remains unpolymerized. Ordinarily, development is accomplished by washing the exposed plate in a solvent which can remove the unpolymerized material while leaving the polymerized (cured) material intact. Since such plates can be formed from a variety of materials, it is necessary to match a specific plate with an appropriate solvent. For example, U.S. Pat. No. 4,323,636, U.S. Pat. No. 4,323,637, U.S. Pat. No. 4,423,135, and U.S. Pat. No. 4,369,246, the disclosures of which are incorporated herein by reference, disclose a variety of photopolymer printing plate compositions based on block copolymers of styrene and butadiene (SBS) or isoprene (SIS). These compositions can be utilized to produce printing plates which can be developed by a number of aliphatic and aromatic solvents, including methyl ethyl ketone, toluene, xylene, d-limonene, carbon tetrachloride, trichloroethane, methyl chloroform, and tetrachloroethylene. These solvents may be used alone or in a mixture with a “non-solvent” (i.e. a substance that cannot dissolve unpolymerized materials), for example, trichloroethane with ethanol. In any case, during the development step, the solvent can be applied in any convenient manner such as by pouring, immersing, spraying, or roller application. Brushing, which aids in the removal of the unpolymerized or uncrosslinked portions of the composition, can also be performed to facilitate the processing of the plate.

Similarly, UK 1,358,062 discloses photosensitive compositions consisting of a nitrile rubber with an addition of photopolymerizable tri- or tetra-unsaturated ester derived from acrylic or methacrylic acid combined with an addition polymerization initiator activated by actinic radiation. Plates made from this composition can be developed by organic solvents including aliphatic esters such as ethyl acetate, aliphatic ketones such as acetone, methyl ethyl ketone, d-limonene, halogenated organic solvents, such as chloroform, methylene chloride, CFC 113 or blends of such solvents. Brushing or agitation can be used to facilitate the removal of the non-polymerized portion of the composition.

U.S. Pat. No. 4,177,074 discloses a photosensitive composition containing a high molecular weight butadiene/acrylonitrile copolymer which contains carboxyl groups, a low molecular weight butadiene polymer which may or may not contain carboxyl groups, and an ethylenically unsaturated monomer, combined with a free-radical generating system. This composition is also used as the polymer layer of a flexographic printing plate and requires processing with such organic solvents as methyl ethyl ketone, benzene, toluene, xylene, d-limonene, trichloroethane, trichlorethylene, methyl chloroform, tetrachloroethylene, or solvent/non-solvent mixtures, e.g., tetrachloroethylene and n-butanol. The composition may also be processed with water-soluble organic solvents in an aqueous basic solution, such as sodium hydroxide/isopropyl alcohol/water; sodium carbonate/isopropyl alcohol/water; sodium carbonate/2-butoxyethanol/water; sodium borate/2-butoxyethanol/water; sodium silicate/2-butoxyethanol/water; sodium borate/2-butoxyethanol/water; sodium silicate/2-butoxyethanol/glycerol/water; and sodium carbonate/2-(2-butoxyethoxy)ethanol/water.

U.S. Pat. No. 4,517,279, the disclosure of which is incorporated herein by reference, discloses a photosensitive composition containing a high molecular weight butadiene acrylonitrile copolymer which contains carboxyl groups, and a high molecular weight butadiene/acrylonitrile copolymer which does not contain carboxyl groups, combined with ethylenically unsaturated monomer and a free radical generating system. That composition, which is also used as the polymer layer of a flexographic printing plate, requires processing by blends of tetrachloroethylene and a non-solvent. The composition may also be processed in mixtures of sodium hydroxide/isopropyl alcohol/water; sodium carbonate/2-butoxyethanol/water; sodium silicate/2-butoxyethanol/water; sodium carbonate/2-butoxyethanol/glycerol/water; and sodium hydroxide/2-(2-butoxyethoxy)ethanol/water.

As can be seen from the foregoing examples of the prior art, the solvents needed for image development will vary depending on the composition of the polymer layer of the plate. The need for different solvent systems is particularly inconvenient, especially if different photopolymer systems are being processed at the same facility. Furthermore, many of the solvents used to develop the plates are toxic or suspected carcinogens. Thus, there exists a need for solvent systems which can be used with a greater degree of safety. In addition, there exists a need for solvent systems which can be used in a variety of plates. U.S. Pat. No. 4,806,452 and U.S. Pat. No. 4,847,182, the disclosures of which are incorporated herein by reference, disclose solvent developers for flexographic plates containing terpene hydrocarbons such as d-limonene which are effective on a variety of plate types. These terpene hydrocarbon-based developers are also non-toxic. However, they have proven to be hazards in the workplace because of their tendency to spontaneously combust thereby causing fires.

Therefore, commonly assigned U.S. Pat. No. 6,248,502 solves the drawbacks of terpene by using terpene esters as a substitute developing solvent. Because terpene ester has a higher flash point, the fire risk is greatly decreased. However, terpene esters tends to breakdown through repeated distillation which limits the recyclability of the solvent.

A big drawback of the prior art developing solvent is the lack of an inexpensive method to reclaim the solvent for subsequent use. Reclamation and recycling of current solvents generally require distillation which is energy and labor intensive.

The present invention relates to an environmentally friendly developing solvent that offers improvement over the prior art. The solvent comprises alkyl esters which have higher flash points when compared to current solvents. For example, d-limonene (a terpene), terpene ester, and methyl ester have a flash points of 120° F., 141° F., and >250° F., respectively. By having a high flash point, alkyl esters offers superior safety in addition to low toxicity, reduced cost, and biodegradability. Furthermore, compared developing solvents of the prior art including terpene ester, alkyl ester causes less plate swelling. Therefore, more alkyl esters (up to 70% by volume) can be used in the developing solvent resulting in faster removal rate of the non-polymerized portion of the plate. Further, after use as a developing solvent, the alkyl esters can be reclaimed and separated from the polymer inexpensively through centrifugation.

### SUMMARY OF THE INVENTION

The present invention relates to ester based solvents for developing printing plates. These solvents, which comprise alkyl esters, either alone or in the presence of other organic materials (co-solvents and non-solvents), can be used with a variety of polymeric systems. The alkyl esters has the general formula RCOOR′, where R can be any organic moiety, preferably and R′ is an alkyl group, preferably having 1 to 12 carbon atoms. The alkyl esters are natural products with low toxicity and are relatively safe to use compared with other solvent systems. The alkyl esters, it has been discovered, provide a unique combination of reduced cost, improved plate quality, low volatility, improved regulatory compliance, low toxicity, reduced washout time, biodegradability, and ease of reclamation.

It is, therefore, an object of the present invention to provide methods of reclaiming and recycling the polymer-contaminated solvent (alkyl esters) that was used in the developing process for the preparation of relief plates crosslinked by photopolymerization. The reclaiming process can be continuous or batch. The process comprises transferring the contaminated solvent, from a plate processor or a dirty holding tank, to a centrifuge, and centrifuging the contaminated solvent to remove the polymer. The reclaimed solvent can be transfer directly back to the plate processor or to a clean holding tank.

### BRIEF DESCRIPTION OF THE DRAWING

FIG. 1 shows an embodiment of the invention where the reclaimed alkyl ester based solvent is associated with a single plate processor.

FIG. 2 shows an embodiment where the reclaimed alkyl ester based solvent is associated with multiple plate processors.

FIG. 3 shows a bowl disc centrifuge.

### DETAILED DESCRIPTION OF THE INVENTION

The present invention comprises alkyl esters based solvents for use in photopolymer printing plate processing. The alkyl esters, which can be used either alone or in a blended form with co-solvents or non-solvents, can be used to develop a number of different photopolymer printing plates. As used herein, co-solvents are non-alkyl ester compounds that can also dissolve the non-polymerized material; and non-solvents are compounds that cannot dissolve the non-polymerized material. The alkyl esters have the general formula RCOOR′, where R can be any organic moiety, and R′ is an alkyl group, preferably having 1 to 12 carbon atoms. R′ can also be a linear or branched alkyl group. Thus, the preferred alkyl esters for this invention includes, but is not limited to, methyl esters, ethyl esters, propyl esters, butyl esters, pentyl esters, hexyl esters, octyl esters, nonyl esters, decyl esters, undecyl esters, dodecyl esters, and any branched compound thereof including isopropyl esters, isobutyl esters, etc. A wide variety of alkyl esters are suitable for use in the solvents of this invention including, but not limited to, alkyl esters of fatty acids with 8-18 carbons.

Mixtures of the alkyl esters can also be used and may show synergistic effects when compared with a alkyl ester used alone. When a combination of two or more alkyl esters is used, the resulting blend is often more effective as a solvent than the individual alkyl ester. This blend is referred to herein as a MAE (Mixed Alkyl Ester) solvent.

Various co-solvents (non-alkyl ester compounds that can also, by themselves, dissolve the non-polymerized material) and non-solvents (compounds that cannot, by themselves, dissolve the non-polymerized material) can also be employed with the alkyl esters and MAE according to the invention. Suitable co-solvents include, but is not limited to, n-butanol, 2-ethoxyethanol, benzyl alcohol, ethanol, methanol, propanol, isopropanol, alpha terpineol, dipropylene glycol methyl ether, 2-butoxyethanol, isopropyl alcohol, and 2-(2-butoxyethoxy) ethanol, cyclopentanol, cyclohexanol, cycloheptanol, substituted cyclopentanol, substituted cyclohexanol, substituted cycloheptanol, cyclopentyl substituted alcohol, cyclohexyl substituted alcohol, and cycloheptyl substituted alcohol.

The co-solvent should be soluble in the alkyl ester or MAE, should have suitable dissolving properties towards the non-photolysed (non-polymerized) portions of the plate that are to be dissolved, should have low toxicity and acceptable safety profiles, and should be readily disposable. The co-solvents are used to modify the properties of the solvent blend. This includes, for example, the addition of co-solvents to aid in the removal of the top protective cover skin on the flexographic plate. In addition, several of the co-solvents, such as terpene alcohols, in particular alpha terpineol, serve as stabilizers to prevent the separation of the solvent blend, which can occur at reduced temperatures. This stabilizer property of the co-solvent becomes important when isoparaffinic hydrocarbons are used as the non-solvent and benzyl alcohol is used as a co-solvent to remove the outer layer of the photopolymerizable printing plate since the benzyl alcohol may separate from the alkyl esters and paraffinic hydrocarbon mixture. Further, the mixture of esters of fatty alcohols and co-solvent is often more effective as a solvent than the individual alkyl ester by itself.

The non-solvent should be miscible with the ester(s) of fatty alcohols ester and the co-solvents, should have acceptable toxicity and safety profiles, and should be readily disposable or recyclable. The non-solvent are typically used as a filler to reduce cost, therefore, recyclability of the non-solvent material is highly desirable. Suitable non-solvents include, but is not limited to, petroleum distillates, such as aliphatic petroleum distillates, naphthas, paraffinic solvents, hydrotreated petroleum distillates, mineral oil, mineral spirits, ligroin, decane, octane, hexane and other similar materials. Isoparaffinic solvents are commercially available in a wide range of volatility and corresponding flash points. The developing solvent of the invention can made with a wide range of commercially available isoparaffinic solvents as its non-solvent base. The following table shows volatilities and properties of commercially available isoparaffinic solvents suitable for use with the invention.

TABLE 1
Volatility

| | | | | | |
|---|---|---|---|---|---|
| Flash Point (° F.) | 106 | 129 | 135 | 147 | 196 |
| Initial Boiling Point (° F.) | 320 | 352 | 350 | 376 | 433 |
| 50% Dry Point (° F.) | 331 | 360 | 365 | 383 | 460 |
| | 345 | 370 | 386 | 405 | 487 |
| Vapor Pressure (mm Hg @ | 14 | 6.2 | 5.7 | 5.2 | 3.1 |
| 100 ° F.) | | | | | |

Parameters such as drying rates, fire risk, workplace air quality and volatile organic compound emissions will also play a role in the selected non-solvent choice.

In addition, in a commercially acceptable product, odor masking materials or perfumes are often added. Such odor masking materials or perfumes can include terpenes to impart a clean, fresh odor.

The developing solvent components can be varied but a suitable composition would be about 30-75% by volume of at least one alkyl ester and preferably a mixture of alkyl esters, about 20-60% by volume of a first co-solvent capable of dissolving the top protective cover layer of the flexographic plate, about 5-35% by volume of a second co-solvent. Optionally less than about 2% by volume of a perfume or odor masking material can be added to the solvent; however, it is important that the perfume must not adversely affect the function of the solvent. A non-solvent can also be included in the solvent in an amount up to about 45% by volume. A preferred composition would be about 50-70% by volume of at least one alkyl ester and preferably a mixture of alkyl esters, about 20-50% by volume of a first co-solvent capable of dissolving the top protective cover layer of the flexographic plate, about 10-30% by volume of a second co-solvent. A non-solvent can also be included in the preferred mixture in an amount up to about 20% by volume. The preferred co-solvents are 2-ethylhexanol and cyclohexanol; and the preferred non-solvent is an isoparaffinic hydrocarbon. The following solvents are especially preferred: 1) about 70% methyl hexadecanoate, about 20% 2-ethylhexanol, and about 10% cyclohexanol; 2) about 80% propyl tetradecanoate and about 20% dodecanol; 3) about 75% isopropyl hexadecanoate and about 25% benzyl alcohol; 4) about 80% ispropyl tetradecanoate and about 20% cyclohexylethanol; and 5) about 75% ethyl hexadecanoate and about 25% dodecanol.

The alkyl ester-based solvents may be substituted for the synthetic hydrocarbon, oxygenated solvents or halogenated hydrocarbon solvents used for processing photopolymer printing plates. For example, the alkyl ester solvents are suitable in the processing of photopolymer printing plates based on block copolymers of styrene and butadiene (SBS) or styrene and isoprene (SIS), copolymers of butadiene and acrylonitrile, terpolymers of butadiene, acrylonitrile and acrylic acid and other similar photopolymers. The alkyl ester-based solvents can be applied to the plates by any conventional application means including spraying, brushing, rolling, dipping (immersing) or any combination thereof. The alkyl ester solvents also produce photopolymer plates with less cured polymer image swelling than those processed in conventional hydrocarbon or chlorinated hydrocarbon solvents. Since swelling tends to distort the image formed, this surprising result permits clear, sharp images to be formed at much lower exposure times than those resulting from the use of conventional solvents. Additionally, the solvents of the invention have fairly low volatility which reduces worker exposure during plate processing. Furthermore, because alkyl esters are natural products, they are much less toxic and are more readily biodegradable than synthetic hydrocarbon or chlorinated hydrocarbon solvents.

After utilization as a developing solvent, the alkyl ester based solvent is contaminated with polymers released from the printing plate. Because the solvent is relatively expensive, it is desirous to be able to recycle the solvent for subsequent developing processes. Applicant has discovered that the present alkyl ester based solvent can be separated from the polymer contaminate simply through centrifugation. The reclaimed solvent has a purity of about 99.5%.

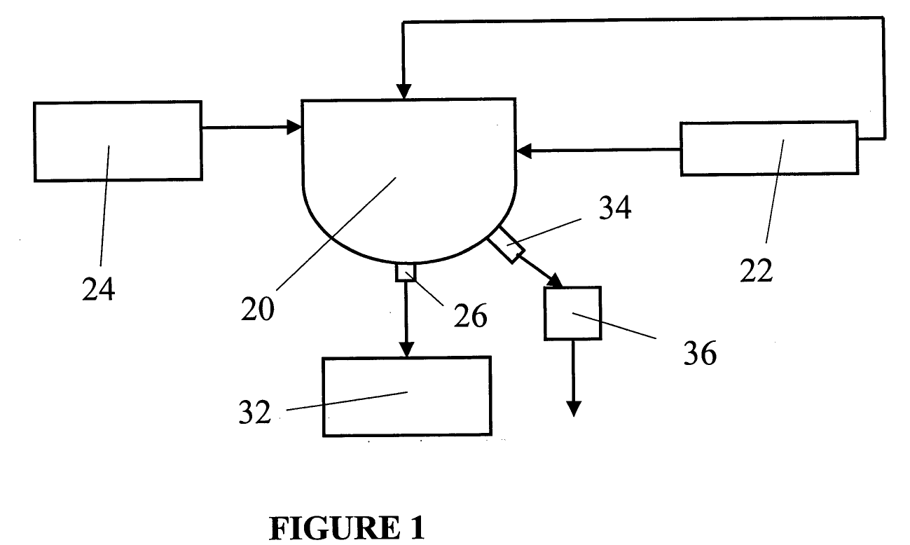

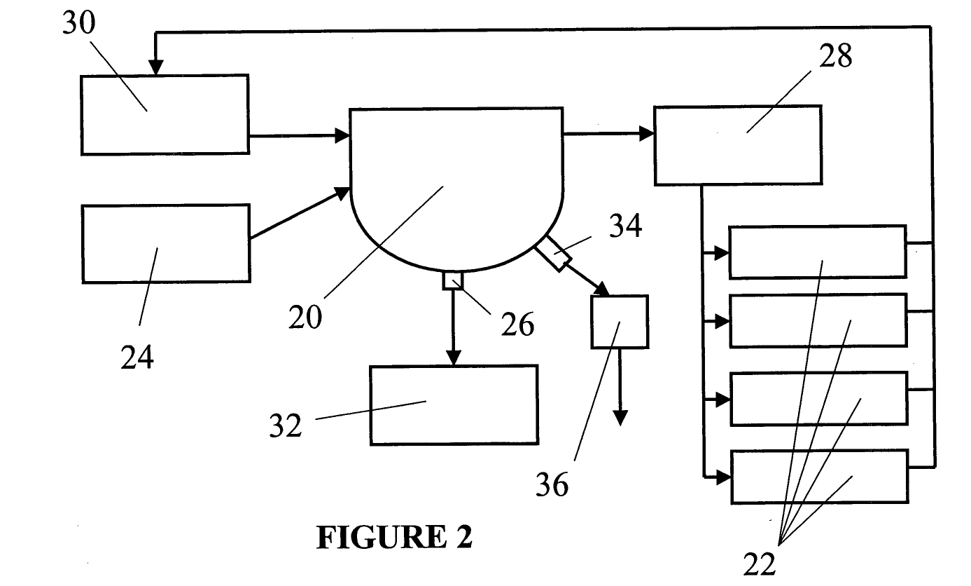

The reclamation process is described in FIGS. 1 and 2. FIG. 1 discloses the reclamation process with a single plate processor set up. The polymer-contaminated solvent from the plate processor 22 is fed into the centrifuge 20, preferably through a conduit. Typically, the polymer-contaminated solvent contains about 3% to about 10% polymer, most preferably about 6% polymer. Because the process yield is generally less than 100%, fresh solvent is also fed into the centrifuge from a replenishment drum 24.

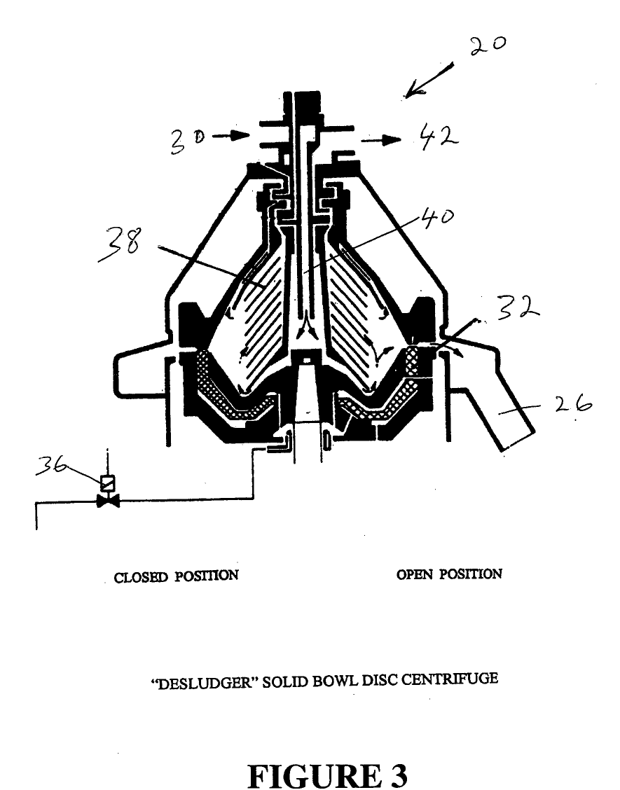

The centrifuged 20 used is preferably, but not limited to, a bowl disc centrifuge shown in FIG. 3. Polymer-contaminated solvent to be purified is fed to the feed port 30 of the centrifuge, from which it flows down the central feed tube 40 and out into the bowl at the bottom of the disc stack 38. While contaminated solvent is fed to the centrifuge at the feed port 30, the moveable piston 32 is in the up or closed position, as controlled by the flow of the centrifuge operating fluid (usually water), which is delivered to the centrifuge by the action of a solenoid valve 36. The solvent flows through the discs 38, which retain polymers more dense than the solvent. The polymer travels to the periphery of the discs and are accelerated to the outermost part of the bowl, where they are collected. The purified solvent transits the disc stack and exits the centrifuge as the clarified product at the exit 42. Periodically, solids are ejected from the centrifuge bowl by briefly opening the moveable piston 32 by means of the operating fluid. The polymer waste stream is ejected from the bowl through the waste port 26. Typically, the centrifuge bowl is open for about 3 second at a time for ejecting the polymer waste from the bowl. During each opening, about 0.017 pounds of solvent is lost per square foot of photopolymer plate processed. The waste is held in a waste holding tank 32 to be prepared for disposal. For safety purposes, the centrifuge may have a pressure relief valve 34 attached to an exhaust fan 36 for venting if excessive pressure is present in the system.

The purified solvent can be fed directly to the plate processor 22 as depicted in FIG. 1 or to a clean holding tank 28 to be prepared for subsequent use. In an embodiment of the invention, the polymer-contaminated solvent is transferred from the plate processors to a dirty holding tank 30 before being fed into the centrifuge. Likewise, the purified solvent exiting the centrifuge is transferred to a clean tank before the solvent is distributed to individual plate processor. The process of FIG. 2 is more flexible than that of FIG. 1 in that the number of operating plate processor can be varied according to the needs and requirements of the overall developing process.

The centrifuge may be any type of centrifuge, preferably a disc centrifuge provided with conical discs and able to centrifuge liquids at high g forces as described above. Depending on the characteristics and throughput of the solvent being processed and the size of the centrifuge bowl, the desludger centrifuge rotational speed should be adjusted so as to provide a centrifugal force of at least about 4,000 g, and preferably between about 4,000 g and 12,000 g. Since the g force is a function of the rotational speed and the radius of the centrifuge bowl, the optimum process g force is limited only by the size of the equipment used and the strength of the stainless steel or other alloy used in the fabrication of the equipment.

The solvent is preferably maintained at room temperature throughout the process. Most preferably, the solvent is maintained at about 70° F. This can be accomplished through cooling and/or heating of the solvent in the piping system and/or the centrifuge. On the other hand, depending on the particular solvent composition, no heating and/or cooling is required as room temperature is sufficient to maintain the solvent temperature in the operating range.

The invention has been disclosed broadly and illustrated in reference to representative embodiments described above. Those skilled in the art will recognize that various modifications can be made to the present invention without departing from the spirit and scope thereof.

What is claimed is:

1. A method for purifying polymer-containing alkyl ester-based solvent comprising the steps of
a) feeding said polymer-containing alkyl ester based solvent into a centrifuge;
b) centrifuging said polymer-containing alkyl ester based solvent to separate the polymer from the alkyl ester based solvent resulting in a polymer-free alkyl ester based solvent; and
c) removing said polymer-free alkyl ester based solvent from the centrifuge.

2. The method of claim 1, wherein the steps comprises a continuous process.

3. The process of claim 1, wherein the process is a batch process.

4. The method of claim 1, wherein the alkyl ester is alkyl ester of fatty acids with 8-18 carbons.

5. The method of claim 1, wherein the polymer is selected from the group consisting of block co-polymers of styrene and butadiene, block co-polymers of styrene and isoprene, co-polymers of butadiene and acrylonitrile, terpolymers of butadiene, acrylonitrile, and acrylic acid.

6. The method of claim 1, wherein said alkyl ester based solvent comprises at least one alkyl ester.

7. The method of claim 6, wherein said alkyl ester based solvent further comprises a co-solvent.

8. The method of claim 7, wherein said alkyl ester based solvent further comprises a non-solvent.

9. The method of claim 1, wherein the centrifuge is a bowl disc centrifuge with conical discs.

10. The method of claim 1, wherein the centrifuging step is performed at g forces of at least about 4000.

11. The method of claim 1, wherein the alkyl ester based solvent is maintained at about 70° F.

12. The method of claim 1, wherein the alkyl group of the alkyl ester has 1 to 12 carbon atoms.
